(19) United States
(12) Patent Application Publication
(10) Pub. No.: US 2017/0338327 A1
(43) Pub. Date: Nov. 23, 2017

(54) SEMICONDUCTOR DEVICE AND MANUFACTURING METHOD THEREOF

(71) Applicants: United Semiconductor (Xiamen) Co., Ltd., Xiamen (CN); UNITED MICROELECTRONICS CORP., Hsin-Chu City (TW)

(72) Inventors: Sheng-Hsu Liu, Changhua County (TW); Jhen-Cyuan Li, New Taipei City (TW); Shui-Yen Lu, Tainan City (TW)

(21) Appl. No.: 15/186,523

(22) Filed: Jun. 19, 2016

(30) Foreign Application Priority Data
May 19, 2016 (CN) 201610340188.3

(51) Int. Cl. H01L 29/66; H01L 21/308; H01L 29/06; H01L 29/78; H01L 21/306

(52) U.S. Cl. CPC H01L 29/66553; H01L 29/785; H01L 29/66795; H01L 21/30604; H01L 29/0642; H01L 21/3085; H01L 29/0657

(57) ABSTRACT

A semiconductor device and a manufacturing method thereof, the semiconductor device includes two gate structures and an epitaxial structure. The two gate structures are disposed on a substrate. The epitaxial structure is disposed in the substrate between the gate structures, wherein a protruding portion of the substrate extends into the epitaxial structure in a protection direction.

### BACKGROUND OF THE INVENTION

### 1. Field of the Invention

The invention relates to a semiconductor device and a method of fabricating the semiconductor device, and more particularly, to a semiconductor device having an epitaxial structure and a method of forming the semiconductor device.

### 2. Description of the Prior Art

In order to increase the carrier mobility of semiconductor structure, it has been widely used to apply tensile stress or compressive stress to a gate channel. For instance, if a compressive stress were to be applied, it has been common in the conventional art to use selective epitaxial growth (SEG) technique to form epitaxial structure such as silicon germanium (SiGe) epitaxial layer in a silicon substrate. As the lattice constant of the SiGe epitaxial layer is greater than the lattice constant of the silicon substrate thereby producing stress to the channel region of PMOS transistor, the carrier mobility is increased in the channel region and speed of MOS transistor is improved accordingly. Conversely, silicon carbide (SiC) epitaxial layer could be formed in silicon substrate to produce tensile stress for gate channel of NMOS transistor.

Despite the aforementioned approach improves the carrier mobility in the channel region, the complexity of the overall process also increases accordingly. For instance, conventional approach typically forms a recess in the silicon substrate, deposits a buffer layer in the recess and then forms an epitaxial layer thereafter. Nevertheless, the buffer layer formed by this approach typically has uneven thickness. This causes negative impacts such as short channel effect or drain induced barrier lowering (DIBL) and degrades the quality and performance of the device.

### SUMMARY OF THE INVENTION

It is therefore an objective of the present invention to provide a semiconductor device which has an improved buffer layer thereto obtain better device performance.

It is therefore an objective of the present invention to provide a fabrication method of a semiconductor device in which an improved buffer layer is formed to resolve the aforementioned issues caused by the defect buffer layer.

To achieve the purpose described above, the present invention provides a semiconductor device including two gate structures and an epitaxial structure. The two gate structures are disposed on a substrate. The epitaxial structure is disposed in the substrate between the gate structures, wherein a protruding portion of the substrate extends into the epitaxial structure in a protection direction.

To achieve the purpose described above, the present invention further provides a method of fabricating a semiconductor device including following steps. First of all, two gate structures are formed on a substrate, a spacer is formed to surround the gate structures. Then, a trench is formed in the substrate between the gate structures by using the spacer as a mask. After that, the spacer is partial removed after the trench is formed, to expose a top surface of a protruding portion of the substrate. Finally, an epitaxial structure is selectively formed in the trench.

Overall, two-stepped or multi-stepped dry etching process is conducted in the fabricating method of the present embodiment to form the trench of perfect circle or circular shape. That is, a portion of the fin-shaped structure (or the substrate) adjacent to the two sides of the trench may form an extended tip toward the trench due to being affected by the circular trench. After that, the spacer used as a mask in the aforementioned two-stepped or multi-stepped dry etching process is partial removed to expose a portion of the extended tip thereto form the protruding portion. Through forming such protruding portion, the buffer layer can be evenly and conformally formed on the surfaces of the trench and the protruding portion while forming the epitaxial structure, thereby making the buffer layer to obtain a uniformed thickness. Thus, by using this approach, the semiconductor device obtained in the present invention may obtain an improved buffer layer thereto avoids the aforementioned issues such as DIBL caused by defect buffer layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 7 are schematic diagrams illustrating a fabricating method of a semiconductor device according to a first embodiment of the present invention; in which:

FIG. 1 shows a semiconductor device at the beginning of the fabricating process;

FIG. 2 shows a semiconductor device after forming a spacer material layer;

FIG. 3 shows a semiconductor device after forming a spacer;

FIG. 4 shows a semiconductor device after forming a primary trench;

FIG. 5 shows a semiconductor device after forming a trench;

FIG. 6 shows a semiconductor device after removing a spacer;

FIG. 7 shows a semiconductor device after forming an epitaxial structure.

FIG. 8 to FIG. 11 are schematic diagrams illustrating a fabricating method of a semiconductor device according to a second embodiment of the present invention, in which:

FIG. 8 shows a semiconductor device after forming another spacer material layer;

FIG. 9 shows a semiconductor device after forming another spacer;

FIG. 10 shows a semiconductor device after forming another trench;

FIG. 11 shows a semiconductor device after forming an epitaxial structure.

### DETAILED DESCRIPTION

To provide a better understanding of the present invention, preferred embodiments will be described in detail. The preferred embodiments of the present invention are illustrated in the accompanying drawings with numbered elements.

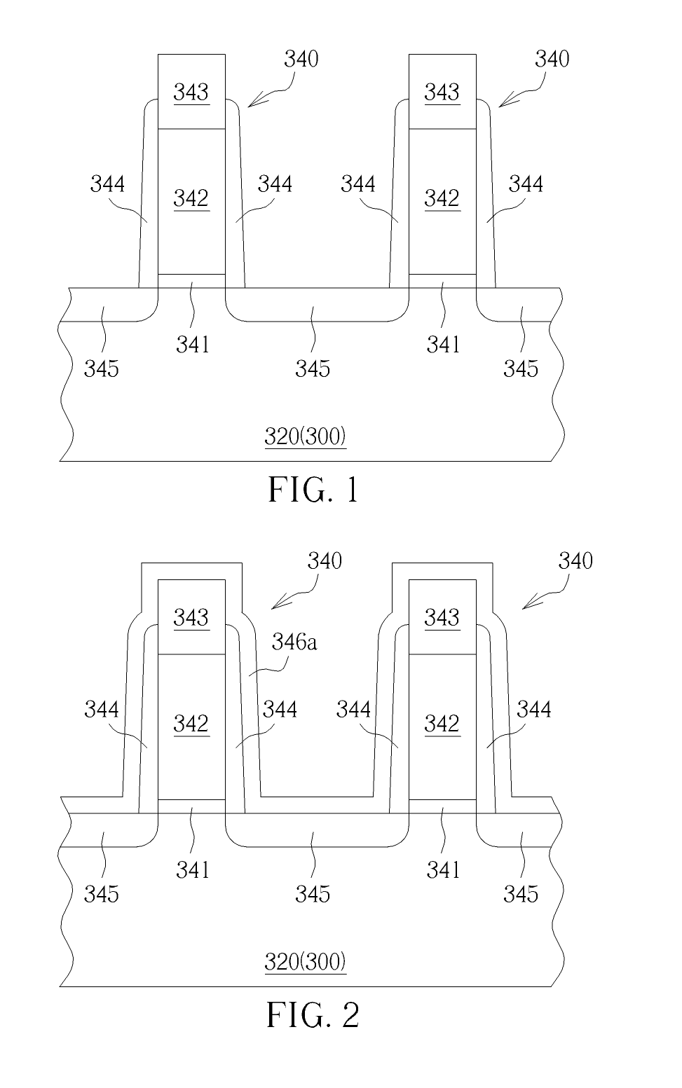

Referring to FIGS. 1-7, FIGS. 1-7 illustrate a fabricating method of a semiconductor device according to a preferred embodiment of the present invention. As shown in FIG. 1, a substrate 300 for example a s silicon substrate, an epitaxial silicon substrate or a silicon-on-insulator (SOI) substrate is first provided, and at least one gate structure 340 is formed on the substrate 300. In the present embodiment, at least one fin-shaped structure 320 and an insulating layer (not shown in the drawings) are formed in the substrate 300, and the gate structure 340 is then formed across the fin-shaped structure 320. In one embodiment, the formation of the fin-shaped structure 320 may be accomplished through a spacer self-aligned double-patterning (SADP) for example including firstly forming a patterned mask (not shown in the drawings) on the substrate 300, transferring patterns of the patterned mask to the substrate 300 through an etching process, and removing the patterned mask, to form a plurality of trenches (not shown in the drawings) in the substrate 300. Next, the insulation layer is then filled in the trenches. That is, a portion of the substrate 300 protruded from the insulation layer forms the fin-shaped structure 320 and the insulation layer forms a shallow trench isolation (STI). It is understood that the fin-shaped structure may also be omitted in another embodiment of the present invention while the formed transistor is a planar transistor, and the gate structure may be formed directly on a planar substrate (not shown in the drawings).

The gate structure 340 includes a gate dielectric layer 341, a dummy gate 342, a capping layer 343 and a spacer 344. The gate dielectric layer 341 may include silicon dioxide (SiO₂) or silicon nitride (SiN). The dummy gate 342 may include polysilicon like undoped polysilicon, doped polysilicon, amorphous silicon or a composite material of the combination thereof. The capping layer 343 may include a multilayer structure or a monolayer structure shown in FIG. 1, for example including SiN, silicon carbide (SiC), silicon carbonitride (SiCN) or a composite material of the combination thereof. The spacer 344 may also include a monolayer structure or a multilayer structure optionally, for example including materials with better spreadability and anti-etching, like high temperature oxide (HTO), SiN, SiO₂, silicon oxynitride (SiON) or SiN formed by hexachlorodisilane (Si₂Cl₆) (HCD-SiN). In one embodiment of the present invention, the method of forming the gate structure 340 includes the following steps. Firstly, a gate dielectric material layer (not shown in the drawings), a dummy gate material layer (not shown in the drawings) and a capping material layer (not shown in the drawings) are stacked one over another on the substrate 300, and then the stacked layers are patterned to form a gate stack structure (not shown in the drawings). Subsequently, two light doped drain region (LDD) region 345 are formed in the fin-shaped structure 320 (namely, the substrate 300) at two sides of the gate stack structure. Then, a first spacer material layer is formed to cover sidewalls of the gate stack structure, another etching process is performed thereto form the spacer 344. However, the formation of the gate structure 340 of the present invention is not limited to the above-mentioned steps but further includes other processes or steps which are well known in the arts. For example, in another embodiment, a metal gate structure (not shown in the drawings) may also be formed on the substrate 300 directly, and the gate structure at least includes a work function layer and a metal gate.

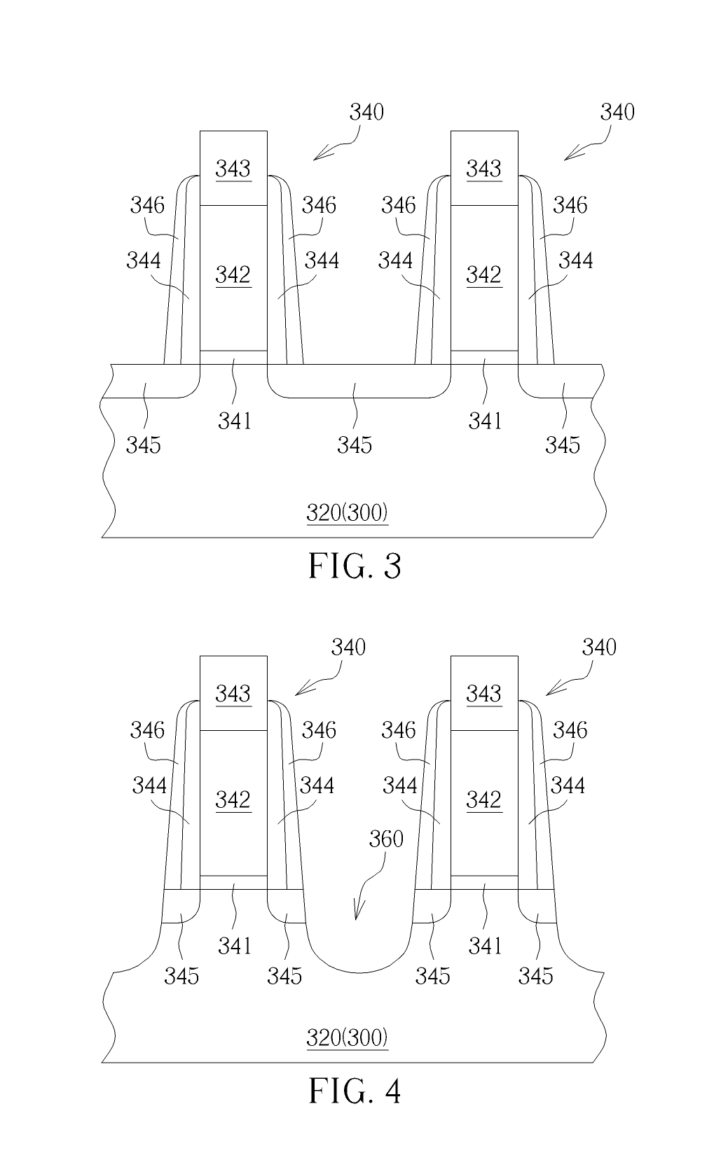

Next, a spacer 346 is formed to surround the spacer 344. In one embodiment, the formation of the spacer 346 may be substantially the same as that of the formation of the spacer 344, and includes firstly forming a second spacer material layer 346a such as SiO₂ or other materials having etching selectivity related to the material of the spacer 344, to cover the fin-shaped structure 320 (namely, the substrate 300) and the spacer 344 as shown in FIG. 2, and performing an etching process such as a dry etching process to form the spacer 346 surrounded the gate structure 340, as shown in FIG. 3. The spacer 346 preferably includes a thickness about 15 to 50 angstroms.

As shown in FIG. 4, a first etching process such as a dry etching process is performed by using the gate structure 340, the spacer 344 and the spacer 346 as a mask, therefore forming a trench 360 at two sides of the gate structure 340 in the fin-shaped structure 320 (or the substrate 300). In other words, the first etching process is conducted to vertically etch the fin-shaped structure 320 along the spacer 344 and the spacer 346, so as to form the trench 360 at two sides of each gate structure 340 in the fin-shaped structure 320 (or the substrate 300), in which the sidewalls of the trench 360 is vertically aligned with the spacer 346 and the bottom portion of the trench 360 reveals a slightly circular profile as shown in FIG. 4.

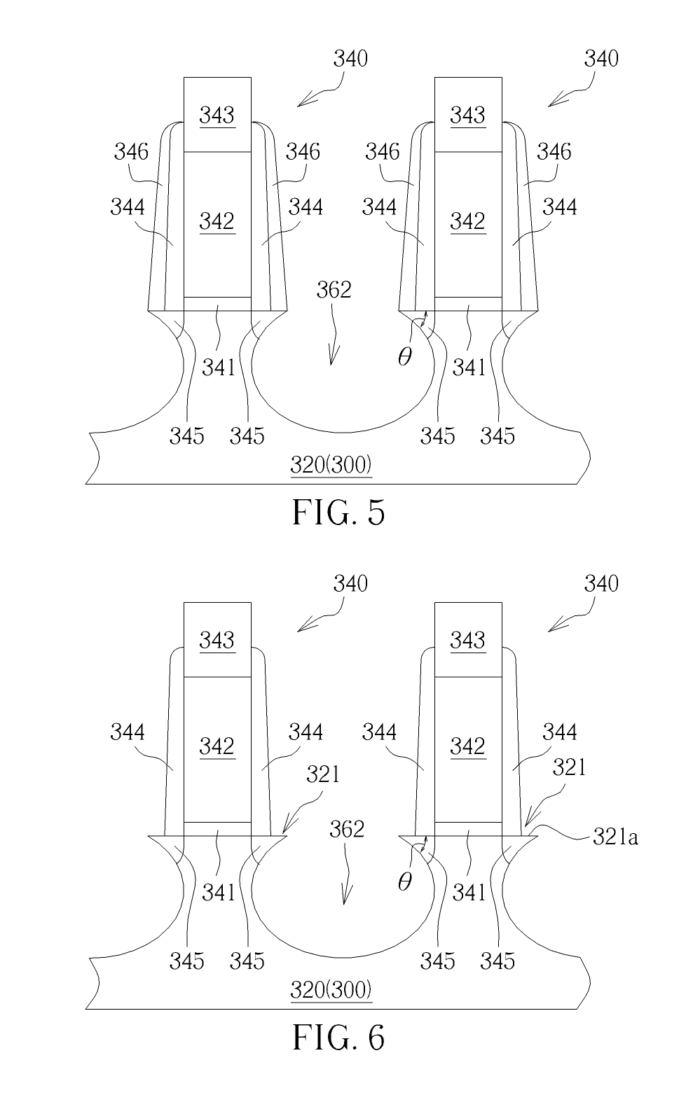

Then, as shown in FIG. 5, a second etching process such as a dry etching process is performed, to further etching the trench 360 formed in the first etching process, particular to further etch the sidewalls thereof. It is noted that the second etching process is conducted to laterally etch the fin-shaped structure 320 (or the substrate 300) under the spacer 346 to further expand the area of the trench 360 and to form a trench 362. Precisely, according to a preferred embodiment of the present invention, the second dry etching process may be accomplished by adjusting the bias power of the processing equipment, such as slightly lowering the bias power to expand the trench 360 by lateral etching. This approach ensures that the trench 360 will not be turned into diamond shaped or hexagonal (or sigma) shaped trench produced by conventional wet etching process, and after the trench 360 is expanded by the lateral etching of the second dry etching process, a substantially trench with a circular shape or preferably the trench 362 of perfect circle is formed in the fin-shaped structure 320 adjacent to the gate structure 340 as shown in FIG. 5. On the other hand, a portion of the fin-shaped structure 320 (or the substrate 300) adjacent to two sides of the trench 362 may form an extended tip toward the trench 362 due to being affected by the circular shape of the trench 362. The extended tip has an acute angle 91 toward the trench 362, and which is about 15 degrees to 45 degrees, as shown in FIG. 5.

It should be noted that even though two dry etching processes are conducted to form the trench 362 of perfect circle or circular shape in this embodiment, the quantity of dry etching process is not limited to two. Also, the trench 362 of perfect circle or circular shape is not limited to be formed only through dry etching process. Instead, the quantity of the dry etching process may be adjusted, or the etching process may also be accomplished through sequential performed dry and wet etching processes depending on the demand of the process and result of the etching process until the trench 362 expands from a slightly rectangular shape from the beginning to a perfect circle, which is also within the scope of the present invention.

After that, the spacer 346 is removed to expose the fin-shaped structure 320 (or the substrate 300) underneath, such that a protruding portion 321 is therefore formed as shown in FIG. 6. Precisely, the protruding portion 321 is namely formed from a portion of the extended tip which is uncovered by the spacer 344. Thus, the protruding portion 321 also has an acute angle 91 toward the trench 362 as shown in FIG. 6. Also, an exposed top surface 321a of the protruding portion 321 preferably has a length about 15 to 50 angstroms.

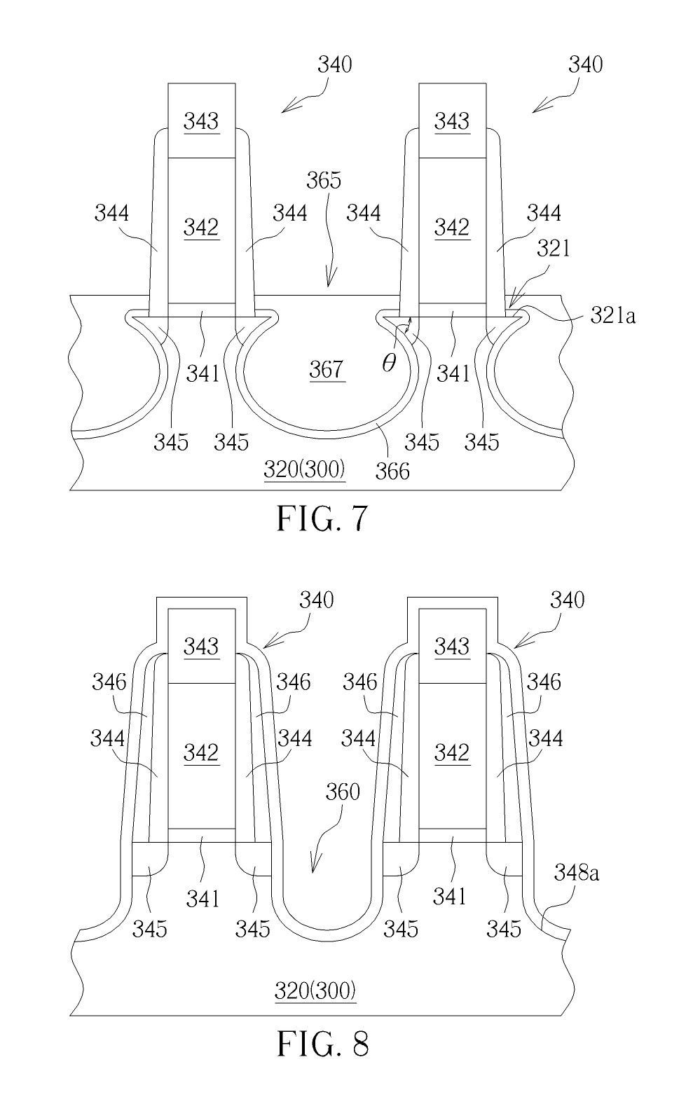

After the trench 362 is formed, a pre-clean process is selectively performed by using a cleaning agent like diluted hydrofluoric acid or SPM containing sulfuric acid, hydrogen peroxide, and deionized water to remove native oxide or other impurities from the surface of the trench 362, and an epitaxial structure 365 is then formed in the trench 362 to fill up the trench 362, as shown in FIG. 7.

The epitaxial structure 365 has a top surface which is higher than the top surface of the fin-shaped structure 320 (or the substrate 300), and the top surface of the epitaxial structure 365 has a length greater than an opening width of the trench 362 as shown in FIG. 7. Precisely speaking, the epitaxial structure 365 may include a first epitaxial layer 366 and a second epitaxial layer 367, in which the first epitaxial layer 366 is conformally grown on the surface of the trench 362 and the surface 321a of the protruding portion 321 thereby covering and directly contacting those surface, so as to performed like a buffer layer. Also, the first epitaxial layer 366 may include a uniformed thickness to completely surround the protruding portion 321, as shown in FIG. 7. Next, the second epitaxial layer 367 is formed on the first epitaxial layer 366 through a selectively epitaxial growth (SEG) process, in which the second epitaxial layer 367 may be formed till filling the trench 362 and being higher than the top surface of the fin-shaped structure 320 (or the substrate 300). That is, the protruding portion 321 of the fin-shaped structure 320 (or the substrate 300) is namely extended into the epitaxial structure 365 in a projection direction being perpendicular to the fin-shaped structure 320 (or the substrate 300) thereto be encompassed by the epitaxial structure 365.

The first epitaxial layer 366 may include pure silicon or silicon with less than 10% dopant; and the second epitaxial layer 367 may includes different materials depending on the demand of the MOS transistor formed subsequently. For example, as the semiconductor device pertains to a PMOS transistor, the second epitaxial layer 367 may preferably be composed of silicon germanium (SiGe), silicon germanium boron (SiGeB) or silicon germanium tin (SiGeSn), but not limited thereto. On the other hand, as the semiconductor device pertains to a NMOS transistor, the second epitaxial layer 367 may preferably be composed of SiC, SiP or SiCP, but not limited thereto. In the present embodiment, the first epitaxial layer 366 and the second epitaxial layer 367 may both include SiGe, in which the germanium concentration of the first epitaxial layer 366 is substantially lower than the germanium concentration of the second epitaxial layer 367, such as less than 10% thereby reducing structural defect of the epitaxial structure 365. Moreover, the epitaxial structure 365 may be formed by the SEG process through a single or a multiple layer approach, and heterogeneous atoms such as germanium or carbon atoms may also be altered in a gradual arrangement, to facilitate the subsequent processes.

Through the aforementioned steps, the semiconductor device according to the first embodiment of the present invention is provided. Following these, an ion implantation process such as an in-situ doping process is performed to form a source/drain (not shown in the drawing) in partial or whole of the epitaxial structure 365; a replacement metal gate process is performed to replace the dummy gate electrode 342 with a metal gate; a silicidation process is performed to form a silicon cap layer on the top surfaces of the source/drain (namely, the epitaxial structure 365) and then to form a silicide layer on at least the partial surface of the source/drain; and/or a contact plug process to form contact plug which is electrically connected to the source/drain and/or the metal gate.

According to the fabricating method of the present embodiment, two-stepped or multi-stepped dry etching process is performed to form the trench of perfect circle or circular shape. That is, a portion of the fin-shaped structure (or the substrate) adjacent to the two sides of the trench may form an extended tip toward the trench due to being affected by the circular shaped trench. After that, the spacer used as a mask in the aforementioned two-stepped or multi-stepped dry etching process is partial removed to expose a portion of the extended tip thereto form the protruding portion. Through forming such protruding portion, the buffer layer can be evenly and conformally formed on the surfaces of the trench and the protruding portion while forming the epitaxial structure, thereby making the buffer layer to obtain a uniformed thickness. Thus, by using this approach, the semiconductor device obtained in the present invention may obtain an improved buffer layer thereto avoids the aforementioned issues such as DIBL caused by defect buffer layer.

The following description will detail other different embodiments or variant embodiments of the fabricating method of the semiconductor device of the present invention. To simplify the description, the following description will detail the dissimilarities among the different embodiments and the identical features will not be redundantly described. In order to compare the differences between the embodiments easily, the identical components in each of the following embodiments are marked with identical symbols.

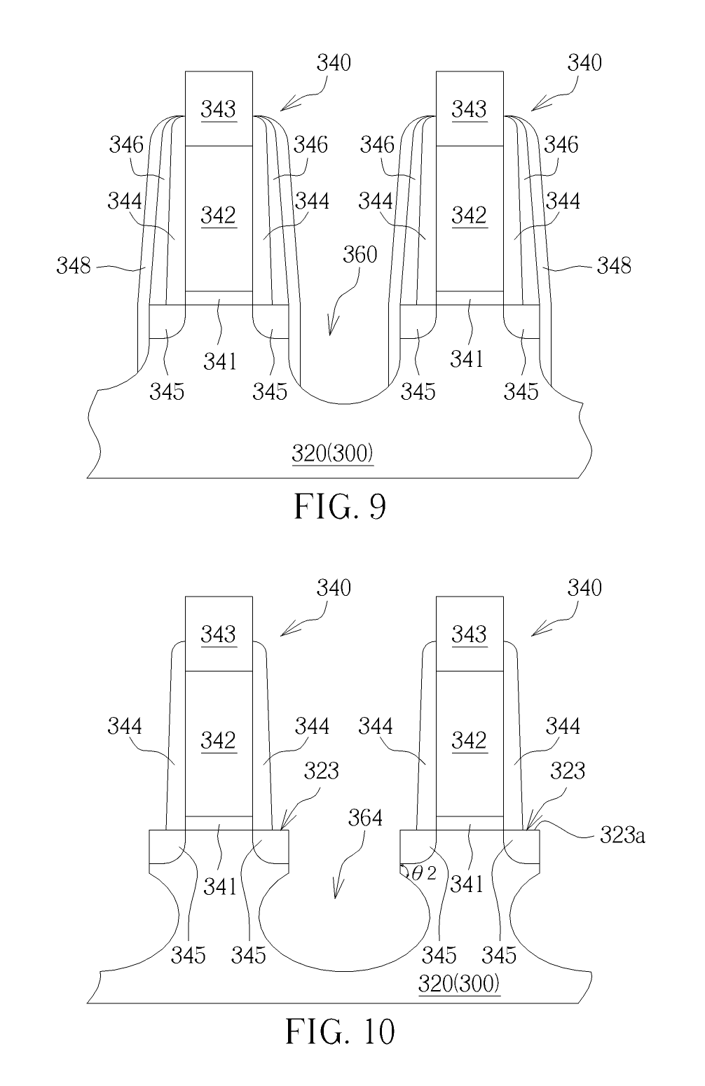

Please refer to FIGS. 8-11, which are schematic diagrams illustrating a fabricating method of a semiconductor device according to the second embodiment of the present invention. The formal steps in the present embodiment are similar to those as in FIGS. 1-4 in the first embodiment and are not redundantly described herein. The differences between the present embodiment and the aforementioned first embodiment are in that after forming the semiconductor structure shown in FIG. 4, a spacer 348 is additionally formed to surround the spacer 346. In one embodiment, the forming process of the spacer 348 is substantially the same as those of the spacers 344, 346. For example, a third spacer material layer 348a is firstly formed to cover the fin-shaped structure 320 (or the substrate 300) and the spacer 346 as shown in FIG. 8, wherein the third spacer material layer 348a may include an easily etched material which has etching selectivity related to the spacer 344 such as SiON, and an etching process, such as a dry etching process is performed to form the spacer 348 surrounded the gate structure 340. It is noted that, the spacer 348 further extends to sidewalls of the trench 360, as shown in FIG. 9.

As shown in FIG. 10, a third etching process such as a dry etching process is performed by using the gate structure 340 and the spacer 348 as a mask, to further etching the trench 360 formed in the first etching process. It is also noted that, due to being covered by the spacer 348, the portion of the sidewall which is covered by the spacer 348 will not be etched in the third etching process. Also, only the fin-shaped structure 320 (or the substrate 300) which is under the spacer 348 is laterally etched to further expand the area of the trench 360 and to form a trench 364.

Precisely, according to a preferred embodiment of the present invention, the third dry etching process may be accomplished by adjusting the bias power of the processing equipment, such as slightly lowering the bias power to expand the trench 360 by lateral etching. This approach ensures that the trench 360 will not be turned into diamond shaped or hexagonal (or sigma) shaped trench produced by conventional wet etching process, and after the trench 360 is expanded by the lateral etching of the third etching process, the substantially trench 364 with a circular shape or preferably a perfect circle is formed in the fin-shaped structure 320 (or the substrate 300) adjacent to the gate structure 340 as shown in FIG. 10. On the other hand, since the spacer 348 partial covers the trench 360 while performing the third etching process, the circular part or the part in perfect circle of the trench 340 is formed in a relative deeper position in the fin-shaped structure 320 (or the substrate 300) in comparison with the trench 362 of the aforementioned first embodiment. On the other hand, the sidewalls of the trench 360 which is covered by the spacer 348 may forms a vertical sidewall being perpendicular to the top surface of the fin-shaped structure 320 (or the substrate 300) as shown in FIG. 10. The vertical sidewall may have a length about 50 to 100 angstroms, but is not limited thereto. In other words, although a portion of the fin-shaped structure 320 (or the substrate 300) adjacent to two sides of the trench 364 may also form an extended tip toward the trench 364 due to being affected by the circular shaped trench 364 while the third etching process in the present embodiment, the extended tip has an obtuse angle θ2 toward the trench 364 as shown in FIG. 10. It is understood that, the third spacer material layer 348a may also be used as a mask while performing an etching process in another embodiment (not shown in the drawing) to further expand the area of the trench 360, such that, the third spacer 348 and the trench 364 may be formed in the same etching process.

Then, the spacer 348 and the spacer 346 are simultaneously removed to expose the fin-shaped structure 320 (or the substrate 300) underneath, such that a protruding portion 323 is therefore formed as shown in FIG. 10. Precisely, the protruding portion 323 is namely formed via the tip which is uncovered by the spacer 344. Thus, the protruding portion 323 also has an obtuse angle θ2 toward the trench 364 as shown in FIG. 10. Also, an exposed top surface 323a of the protruding portion 323 preferably has a length about 15 to 50 angstroms.

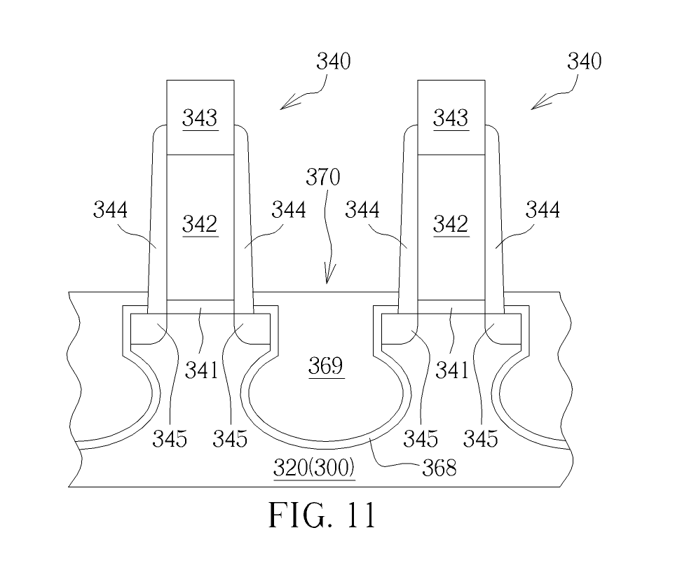

After the trench 364 is formed, a pre-clean process is selectively performed by using a cleaning agent like diluted hydrofluoric acid or SPM containing sulfuric acid, hydrogen peroxide, and deionized water to remove native oxide or other impurities from the surface of the trench 364, and an epitaxial structure 370 is then formed in the trench 364 to fill up the trench 364, as shown in FIG. 11.

The epitaxial structure 370 has a top surface which is higher than the top surface of the fin-shaped structure 320 (or the substrate 300). Precisely speaking, the epitaxial structure 370 may include a first epitaxial layer 368 and a second epitaxial layer 369, in which the first epitaxial layer 368 is conformally grown on the surface of the trench 364 and the surface 323a of the protruding portion 323 thereby covering and directly contacting those surface, so as to performed like a buffer layer. Also, the first epitaxial layer 368 may include a uniformed thickness to completely surround the protruding portion 323, as shown in FIG. 11. Next, the second epitaxial layer 369 is formed on the first epitaxial layer 368 through a selectively epitaxial growth (SEG) process, in which the second epitaxial layer 369 may be formed till filling the trench 364 and being higher than the top surface of the fin-shaped structure 320 (or the substrate 300). That is, the protruding portion 323 of the fin-shaped structure 320 (or the substrate 300) is namely extended into the epitaxial structure 370 in a projection direction being perpendicular to the fin-shaped structure 320 (or the substrate 300) thereto be encompassed by the epitaxial structure 370.

The first epitaxial layer 368 may include pure silicon or silicon with less than 10% dopant; and the second epitaxial layer 369 may includes different materials depending on the demand of the MOS transistor formed subsequently. For example, as the semiconductor device pertains to a PMOS transistor, the second epitaxial layer 369 may preferably be composed of silicon germanium (SiGe), silicon germanium boron (SiGeB) or silicon germanium tin (SiGeSn), but not limited thereto. On the other hand, as the semiconductor device pertains to a NMOS transistor, the second epitaxial layer 369 may preferably be composed of SiC, SiP or SiCP, but not limited thereto. In the present embodiment, the first epitaxial layer 368 and the second epitaxial layer 369 may both include SiGe, in which the germanium concentration of the first epitaxial layer 368 is substantially lower than the germanium concentration of the second epitaxial layer 369, such as less than 10% thereby reducing structural defect of the epitaxial structure 370. Moreover, the epitaxial structure 370 may be formed by the SEG process through a single or a multiple layer approach, and heterogeneous atoms such as germanium or carbon atoms may also be altered in a gradual arrangement, to facilitate the subsequent processes.

Through the aforementioned steps, the semiconductor device according to the second embodiment of the present invention is provided. Following these, an ion implantation process such as an in-situ doping process is performed while forming the second epitaxial layer 369 to form a source/drain (not shown in the drawing) in partial or whole of the epitaxial structure 370; a replacement metal gate process is performed to replace the dummy gate electrode 342 with a metal gate; a silicidation process is performed to form a silicon cap layer on the top surfaces of the source/drain (namely, the epitaxial structure 370) and then to form a silicide layer on at least the partial surface of the source/drain; and/or a contact plug process to form contact plug which is electrically connected to the source/drain and/or the metal gate.

According to the fabricating method of the present embodiment, a spacer is additionally formed on sidewalls of a primary trench formed in the first dry etching process, and another dry etching process or a multi-stepped dry etching process is then performed to form the trench of perfect circle or circular shape. That is, a portion of the fin-shaped structure (or the substrate) adjacent to the two sides of the trench may form an extended tip toward the trench (or the epitaxial structure filled in the trench) due to being affected by the circular shaped trench. After that, the spacer used as a mask in the aforementioned multi-stepped dry etching process is partial removed to expose a portion of the extended tip thereto form the protruding portion. Through forming such protruding portion, the buffer layer can be evenly and conformally formed on the surfaces of the trench and the protruding portion while forming the epitaxial structure, thereby making the buffer layer to obtain a uniformed thickness. Thus, by using this approach, the semiconductor device obtained in the present invention may obtain an improved buffer layer thereto avoids the aforementioned issues such as DIBL caused by defect buffer layer.

It should further be noted that despite the aforementioned embodiments pertains to non-planar type transistors such as FinFETs, the process of the present invention could also be applied to planar transistors, which is also within the scope of the present invention.

Those skilled in the art will readily observe that numerous modifications and alterations of the device and method may be made while retaining the teachings of the invention. Accordingly, the above disclosure should be construed as limited only by the metes and bounds of the appended claims.

1. A semiconductor device, comprising:
two gate structures disposed on a substrate; and
an epitaxial structure disposed in the substrate between the two gate structures, wherein a protruding portion of the substrate extends into the epitaxial structure in a protection direction, the epitaxial structure directly contacts a top surface of the protruding portion which is leveled with a top surface of the substrate.

2. The semiconductor device according to claim 1, further comprising:
a first spacer, and a top surface of the protruding portion being uncovered from the first spacer.

3. (canceled)

4. The semiconductor device according to claim 1, wherein the protruding portion of the substrate comprises an acute angle extended toward the epitaxial structure.

5. The semiconductor device according to claim 1, wherein the protruding portion of the substrate comprises an obtuse angle extended toward the epitaxial structure.

6. The semiconductor device according to claim 1, wherein the protruding portion of the substrate comprises a sidewall being perpendicular to a top surface of the substrate.

7. The semiconductor device according to claim 1, wherein a top surface of the epitaxial structure is higher than a top surface of the substrate.

8. The semiconductor device according to claim 1, wherein the epitaxial structure comprises:
a first epitaxial layer; and
a second epitaxial layer disposed on the first epitaxial layer.

9. The semiconductor device according to claim 8, wherein the first epitaxial layer encompass the protruding portion of the substrate.

10. The semiconductor device according to claim 1, further comprising:
a fin shaped structure disposed in the substrate and the two gate structures disposed across the fin shaped structure.

11. A method of forming a semiconductor device, comprising:
forming two gate structures on a substrate;
forming a spacer surrounded each of the gate structures;
forming a trench in the substrate between the gate structures by using the spacer as a mask;
partially removing the spacer after the trench being formed to expose a top surface of a protruding portion of the substrate; and
selectively forming an epitaxial structure in the trench.

12. The method of forming the semiconductor device according to claim 11, wherein the protruding portion of the substrate extends into the epitaxial structure in a protection direction.

13. The method of forming the semiconductor device according to claim 11, wherein the top surface of the protruding portion of the substrate directly contacts the epitaxial structure.

14. The method of forming the semiconductor device according to claim 11, wherein the spacer comprises a first spacer and a second spacer, and the second spacer is removed while the partially removing of the spacer.

15. The method of forming the semiconductor device according to claim 14, wherein the forming of the spacer comprises:
forming a first material layer on the substrate, covering the gate structures;
performing a first etching process to form the first spacer;
forming a second material layer on the substrate, covering the gate structures; and
performing a second etching process to form the second spacer.

16. The method of forming the semiconductor device according to claim 15, wherein the second material layer is formed after the first spacer is formed.

17. The method of forming the semiconductor device according to claim 14, wherein the forming of the trench comprises:
vertically etching the substrate to form a primary trench which is vertical aligned with the second spacer;
forming a third material layer covered the second spacer, the first spacer and the gate structures;
forming the third spacer surrounded the second spacer and the first spacer; and
further etching the primary trench to form the trench.

18. The method of forming a semiconductor device according to claim 17, further comprising:
removing the third spacer while the partially removing of the spacer.

19. The method of forming the semiconductor device according to claim 17, wherein the third spacer is formed while the trench is form.

20. The method of forming the semiconductor device according to claim 11, wherein the forming of the epitaxial structure comprises:
forming a first epitaxial layer on surfaces of the protruding portion and the trench; and
forming a second epitaxial layer to fill the trench.
